(19) United States
(12) Patent Application Publication
(10) Pub. No.: US 2020/0296534 A1
(43) Pub. Date: Sep. 17, 2020

(54) SOUND PLAYBACK DEVICE AND OUTPUT SOUND ADJUSTING METHOD THEREOF

(71) Applicant: Unlimiter MFA Co., Ltd., Eden Island, SC (US)

(72) Inventors: Cheng-Te WANG, Taipei (TW); Kuo-Wei KAO, Taipei (TW); Kuan-Li CHAO, Taipei (TW); Kuo-Ping YANG, Taipei (TW)

(21) Appl. No.: 16/705,358

(22) Filed: Dec. 6, 2019

(30) Foreign Application Priority Data
Mar. 11, 2019 (TW) 108108083

(51) Int. Cl. H04S 7/00; H03G 5/16

(52) U.S. Cl. CPC H04S 7/307; H04S 2400/13; H03G 5/165

(57) ABSTRACT

A sound playback system and an output sound adjusting method thereof are disclosed. The method includes the follow steps: obtaining an input sound signal and knowing an average input volume of the input sound signal; detecting an ambient noise, and analyzing an average noise volume and a noise frequency hand of the ambient noise; determining whether the average noise volume of the ambient noise is louder than the average input volume; if yes, adjusting a specific frequency band of the input sound signal to increase a first gain value to form an output sound signal, wherein the specific frequency band and the noise frequency band of the ambient noise belongs to the same frequency band or different frequency bands; and playing the output sound signal.

### BACKGROUND OF THE INVENTION

### 1. Field of the Invention

The present invention relates to a sound playback device and an output sound adjusting method thereof particularly to a sound playback device and an output sound adjusting method thereof that can be adjusted according to the frequency range of external noise.

### 2. Description of the Related Art

Nowadays, it is common for users to listen to sounds using devices such as stereos, Walkman or smart phones. But when listening to the sound signal, it may also be disturbed by external noise. in the prior art, it is usually necessary to shield all external noise. However, this method is costly. if it is used for the speaker to listen to the sound, it cannot achieve the effect of shielding the external noise. Another method is to increase the volume of the sound signal to cover the external noise when there is external noise. However, this method cannot make proper adjustments to the frequency range of external noise, and eventually the effect of the user's listening is not fine enough.

Accordingly, it is necessary to devise a new sound playback device and an output sound adjusting method thereof to solve the problem in the prior art.

### SUMMARY OF THE INVENTION

It is a major objective of the present invention to provide a sound playback system that can be adjusted according to the frequency range of external noise.

It is another objective of the present invention to provide an output sound adjusting method used for the aforementioned sound playback system.

To achieve the above objectives, the sound playback device of the present invention includes a sound receiving module, a noise detector, a noise analysis module, a sound processing module, and a speaker module. The sound receiving module is used to obtain an input sound signal and know an average input volume of the input sound signal. The noise detector is used to detect an ambient noise. The noise analysis module is electrically connected to the noise detector for analyzing an average noise volume and a noise frequency band of the ambient noise. The sound processing module is electrically connected to the sound receiving module and the noise analysis module to determine whether he average noise volume of the ambient noise is louder than the average input volume. If yes, the sound processing module adjusts a specific frequency band of the input sound signal to increase a first gain value to form an output sound signal, wherein the specific frequency band and the noise frequency band of the ambient noise belongs to the same frequency band or different frequency hand, The speaker module is electrically connected to the sound processing module for playing the output sound signal.

An output sound adjusting method of the present invention includes the following steps: obtaining an input sound signal and knowing an average input volume of the input sound signal; detecting an ambient noise, and analyzing an average noise volume and a noise frequency band of the ambient noise; determining whether the average noise volume of the ambient noise is louder than the average input volume; if yes, adjusting a specific frequency band of the input sound signal to increase a first gain value to form an output sound signal, wherein the specific frequency band and the noise frequency band of the ambient noise belongs to the same frequency band or different frequency band; and playing the output sound signal.

### BRIEF DESCRIPTION OF THE DRAWINGS

FIG. 1 is an architecture diagram of a sound playback device in the present invention;

FIG. 2 is a flowchart showing steps of an output sound adjusting method in the present invention;

FIG. 3 is a waveform diagram of adjusting output sound in a first embodiment of the present invention;

FIG. 4 is a waveform diagram of adjusting output sound in a second embodiment of the present invention;

FIG. 5 is a waveform diagram of adjusting output sound in a third embodiment of the present invention;

FIG. 6 is a waveform diagram of adjusting output sound in a fourth embodiment of the present invention;

FIG. 7 is a waveform diagram of adjusting output sound in a fifth embodiment of the present invention; and

FIG. 8 is a waveform diagram of adjusting output sound in a sixth embodiment of the present invention.

### DETAILED DESCRIPTION OF THE PREFERRED EMBODIMENT

Hereafter, the technical content of the present invention will be better understood with reference to preferred embodiments.

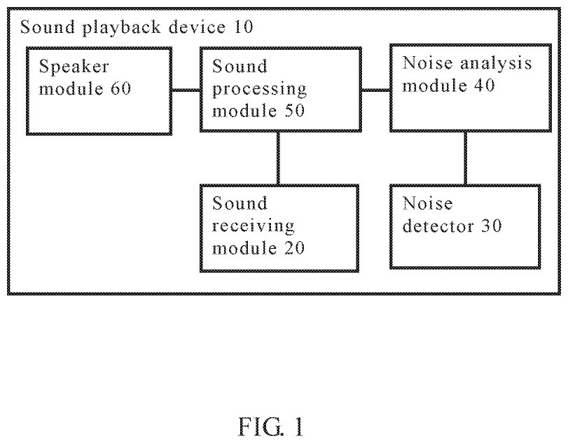

Hereafter, please refer to FIG. 1, which is an architecture diagram of a sound playback device in the present invention.

A sound playback device 10 of the present invention includes a sound receiving module 20, a noise detector 30, a sound processing module 50, and a speaker module 60. The sound receiving module 20 is used to obtain an input sound signal, and know an average input volume of the input sound signal. In different embodiments of the present invention, the sound receiving module 20 may be a microphone or other signal receiving device to receive sound signals generated by the external or other devices. However, the present invention does not limit the sound receiving mode or receiving path of the sound receiving module 20.

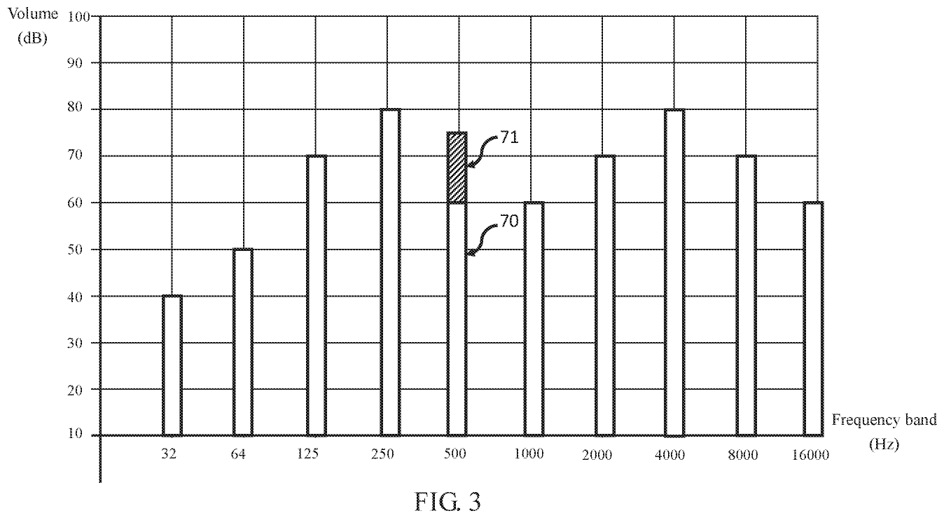

The noise detector 30 can be a microphone, which is electrically connected to the sound receiving module 20 for detecting ambient noise outside the sound playback device 10. The noise analysis module 40 is electrically connected to the noise detector 30 for analyzing the average noise volume of the ambient noise obtained by the noise detector 30 and knowing a noise frequency band of the ambient noise. For example, as shown in FIG. 3, the noise detector 30 can know that the ambient noise belongs to a frequency band of 32 Hz, 64 Hz, 125 Hz, 250 Hz, 500 Hz, 1000 Hz, 2000 Hz, 4000 Hz, 8000 Hz or 16000 Hz, or the ambient noise can also be distributed to more than one frequency band simultaneously. The above-mentioned frequency bands are only illustrative, and the present invention is not limited thereto. The noise analysis module 40 can determine whether the average noise volume of the ambient noise is louder than the average input volume. If yes, the noise analysis module 40 can further determine whether the volume difference of the average noise volume and the average input volume exceeds a threshold. For example, when the average input volume of the input sound signal is 60 dB, if the average noise volume of the ambient noise exceeds the average input volume by 20 dB, it is determined that the average noise volume of the ambient noise exceeds the threshold. However, the present invention does not limit the set threshold value.

The sound processing module 50 is electrically connected to the sound receiving module 20 and the noise analysis module 40. The sound processing module 50 can be an equalizer (EQ) used to adjust the gain value of the sound signal band. The equalizer is a tool that can be used with adjustable sound output to change a gain value of sounds in different frequency bands, so it is often used to adjust the output sound. When the noise analysis module 40 determines that the average noise volume of the ambient noise is louder than the average input volume, the sound processing module 50 can adjust the volume of the specific sound band according to the volume characteristic of the ambient noise to increase a first gain value to form an output sound signal. Here, the specific frequency band and the noise frequency band of the ambient noise belong to the same frequency band or different frequency bands. The sound processing module 50 can also adjust other input sound signals that do not belong to the specific frequency band. When the volume difference of the average noise volume and the average input volume exceeds a threshold, the sound processing module 50 can increase a second gain value for other input sound signals that do not belong to the specific frequency band. When the volume difference of the average noise volume and the average input volume is less than the threshold, the sound processing module 50 can decrease the second gain value for other input sound signals that do not belong to the specific frequency band. Specifically, the second gain value is less than the first gain value. That is, the sound processing module 50 does not perform the same volume adjustment for all the bands of the input sound signal. The sound processing module 50 can only adjust the frequency band of the input sound signal that is the same as the noise frequency band, or only adjust the frequency band of the input sound signal that is different from the noise frequency band. Furthermore, the sound processing module 50 can adjust all the frequency bands of the input sound signal, but the adjustment of the specific frequency band is different from that of the non-specific frequency band. The degree of adjustment is changed according to the noise frequency band of the ambient noise, and the present invention is not limited to only adjusting the two gain values. The sound processing module 50 can also adjust three or more gain values simultaneously,

Finally, the speaker module 60 is electrically connected to the sound processing module 50 for playing the output sound signal, The speaker module 60 can be a headset or a speaker, but the present invention is not limited thereto. in this way, the output sound signal played by the speaker module 60 can reduce the interference of external noise when the user uses it.

it should be noted that each module of the sound playback device 10 may be configured as a hardware device, software program with hardware device, or firmware with hardware device, e.g. a computer program product stored in a computer readable medium and read and executed to achieve the functions of the present invention. However, the present invention is not limited to the above-described manner. Additionally, the preferred embodiments of the present invention described above are only illustrative. To avoid redundancy, all the possible combinations of changes are not documented in detail. However, it shall be understood by those skilled in the art that each of the modules or elements described above may not be necessary. For the implementation of the present invention, the present invention may also contain other detailed, conventional modules or elements. Each module or component is likely to be omitted or modified depending on the needs. Other modules or elements may at necessarily exist between two of any modules.

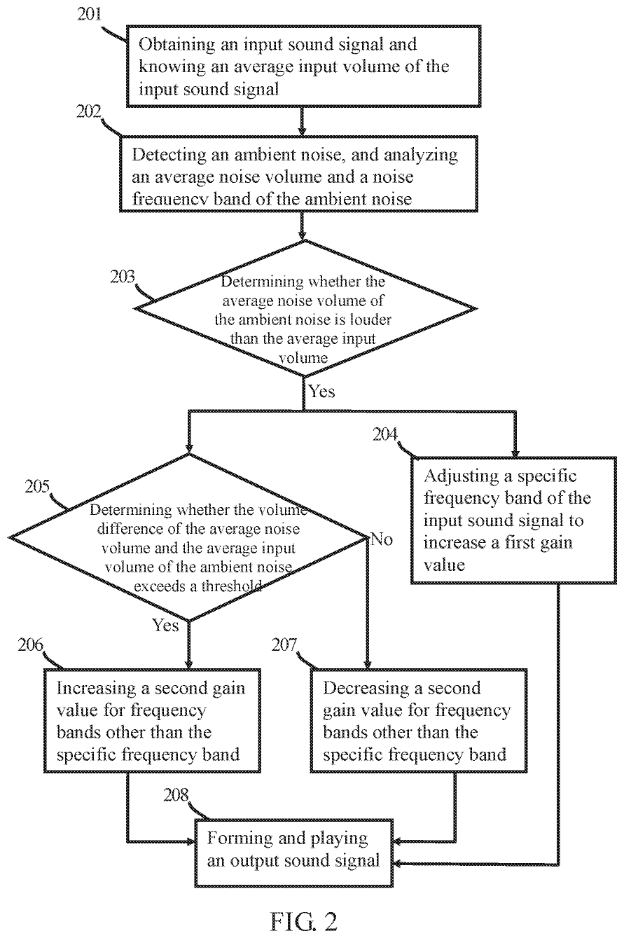

Then, please refer to FIG. 2, which is a flowchart showing steps in an output sound adjusting method of the present invention. It should be noted here that although the aforementioned sound playback device 10 is taken as an example to illustrate an output sound adjusting method of the present invention, the output sound adjusting method in the present invention is not limited to the sound playback device 10 using the same structure as described above.

First, the sound playback device 10 performs Step 201: Obtaining an input sound signal and knowing an average input volume of the input sound signal.

The sound receiving module 20 first obtains an input sound signal, such as the sound signal generated by the external or other device, but the present invention is not limited thereto. Also, the sound receiving module 20 can also know an average input volume of the input sound signal.

Then, in Step 202: Detecting an ambient noise, and analyzing an average noise volume and a noise frequency band of the ambient noise.

The noise detector 30 detects the ambient noise outside the is sound playback device 10, analyzes the average noise volume of the ambient noise obtained by the noise detector 30 by using the noise analysis module 40, and knows a noise frequency band of the ambient noise. The noise analysis module 40 can find out which frequency band the noise frequency band belongs to, such as 32 Hz, 64 Hz, 125 Hz, 250 Hz, 500 Hz, 1000 Hz, 2000 Hz; 4000 Hz, 8000 Hz or 16000 Hz, but the present invention is not limited thereto.

Next, the sound processing module 50 performs Step 203: Determining whether the average noise volume of the ambient noise is louder than the average input volume.

The noise analysis module 40 then determines whether the average noise volume of the ambient noise is louder than the average input volume

When the average noise volume of the ambient noise is louder than the average input volume, the sound processing module 50 can perform Step 204: Adjusting a specific frequency band of the input sound signal to increase a first gain value.

The sound processing module 50 can adjust a specific frequency band of the input sound signal to increase a first gain value to form an output sound signal. Here, the specific frequency band and the noise frequency band of the ambient noise belong to the same frequency band or different frequency bands. Accordingly, hereafter please refer to FIG. 3, which is a waveform diagram of adjusting output sound in a first embodiment of the present invention.

In the first embodiment of the present invention, the specific frequency band and the noise frequency band of the ambient noise belongs to the same frequency band. Therefore, after the noise analysis module 40 confirms that the noise frequency band is 500 Hz, the sound processing module 50 increases the first gain value 71 to the original gain value 70 of the input sound signal belonging to the 500 Hz band. The first gain value 71 can be 15 dB or greater than 15 dB, but the present invention is not limited thereto. Therefore, the output sound signal of the 500 Hz band is equivalent to the original gain value 70 plus the first gain value 71.

In addition, after Step 203, Step 205 can also be simultaneously performed: Determining whether the volume difference of the average noise volume and the average input volume of the ambient noise exceeds a threshold.

The noise analysis module 40 can further determine whether the volume difference of the average noise volume and the average input volume exceeds a threshold,

If the volume difference of the average noise volume and the average input volume exceeds a threshold, Step 206 will be performed: Increasing a second gain value for frequency bands other than the specific frequency band.

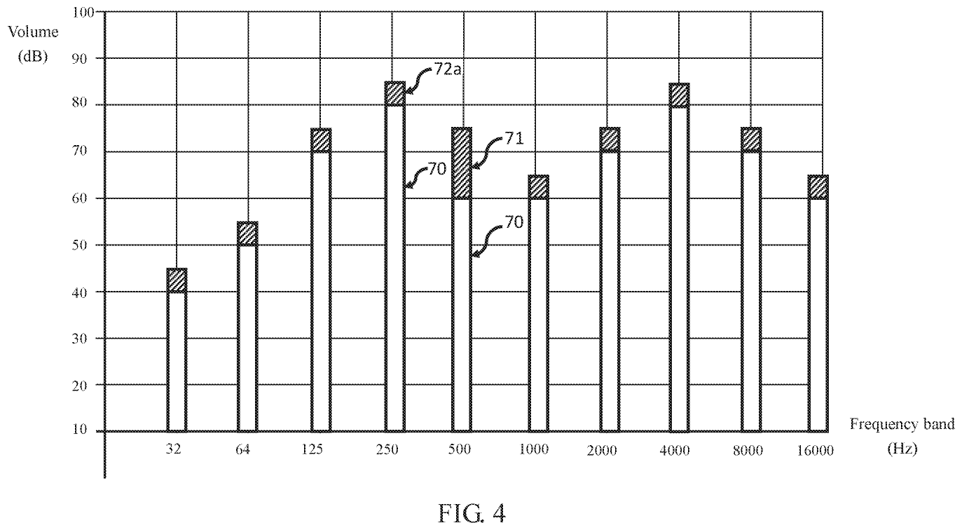

When the volume difference of the average noise volume and the average input volume exceeds a threshold, the sound processing module 50 can increase a second gain value for other input sound signals that do not belong to the specific frequency band. Hereafter, please refer to FIG. 4, which is a waveform diagram of adjusting output sound in a second embodiment of the present invention.

In the second embodiment of the present invention, the sound processing module 50 not only increases the first gain value 71 to the original gain value 70 of the input sound signal belonging to the 500 Hz band, but increases the second gain value 72a to the original gain value 70 of the input sound signal belonging to other frequency bands. Specifically, the second gain value 72a is less than the first gain value 71, e.g. 0-5 dB, but the present invention is not limited thereto. Therefore, the output sound signal outside the 500 Hz band is equivalent to the original gain value 70 plus the second gain value 72a.

If the volume difference of the average noise volume and the average input volume is less than a threshold, Step 207 will be performed: Decreasing a second gain value for frequency bands other than the specific frequency band.

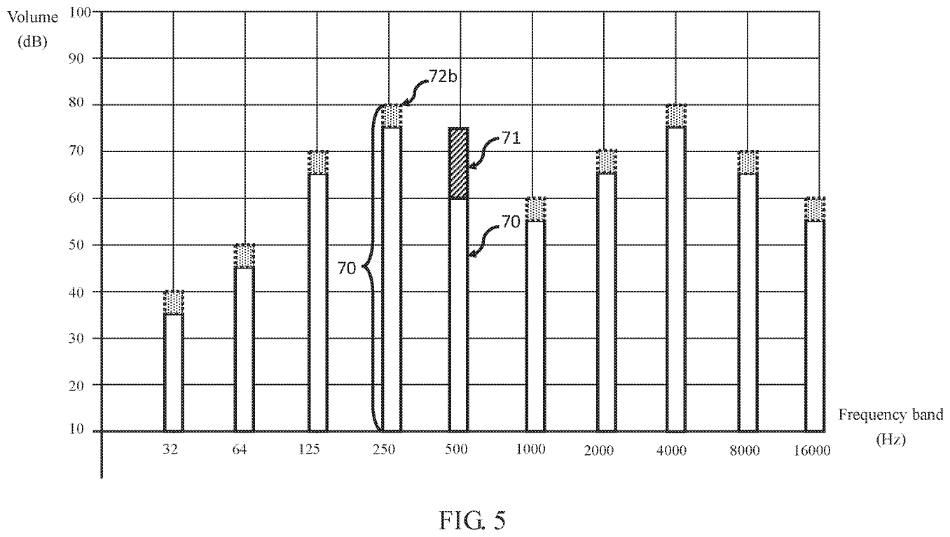

When the volume difference of the average noise volume and the average input volume is less than the threshold, the sound processing module 50 can decrease a second gain value 72b for other input sound signals that do not belong to the specific frequency band. Then, please refer to FIG. 5, which is a waveform diagram of adjusting output sound in a third embodiment of the present invention.

In the third embodiment of the present invention, the sound processing module 50 not only increases the first gain value 71 to the original gain value 70 of the input sound signal belonging to the 500 Hz band, but decreases the second gain value 72b from the original gain. value 70 of the input sound signal belonging to other frequency bands. Similarly, the second gain value 72b is less than the first gain value 71, e.g. 0-5 dB, but the present invention is not limited thereto, Therefore, the output sound signal outside the 500 1-lz hand is equivalent to the original gain value 70 minus the second gain value 72b.

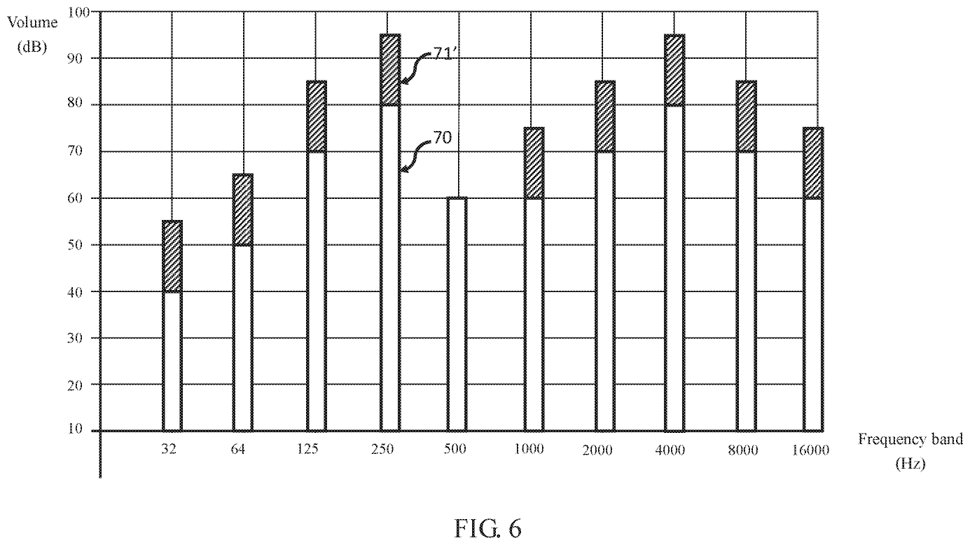

Then, please refer to FIG. 6, which is a waveform diagram of adjusting output sound in a fourth embodiment of the present invention.

In the fourth embodiment of the present invention, the specific frequency band and the noise frequency band of the ambient noise belong to different frequency bands. Therefore, after the noise analysis module 40 confirms that the noise frequency band is 500 Hz, the sound processing module 50 increases the first gain value 71′ to the original gain value 70 of the input sound signal that does not belong to the 500 Hz band. The first gain value 71′ can also be 15 dB or greater than 15 dB, but the present invention is not limited thereto. Therefore, the output sound. signal outside the 500 Hz band is equivalent to the original gain value 70 plus the first gain value 71′.

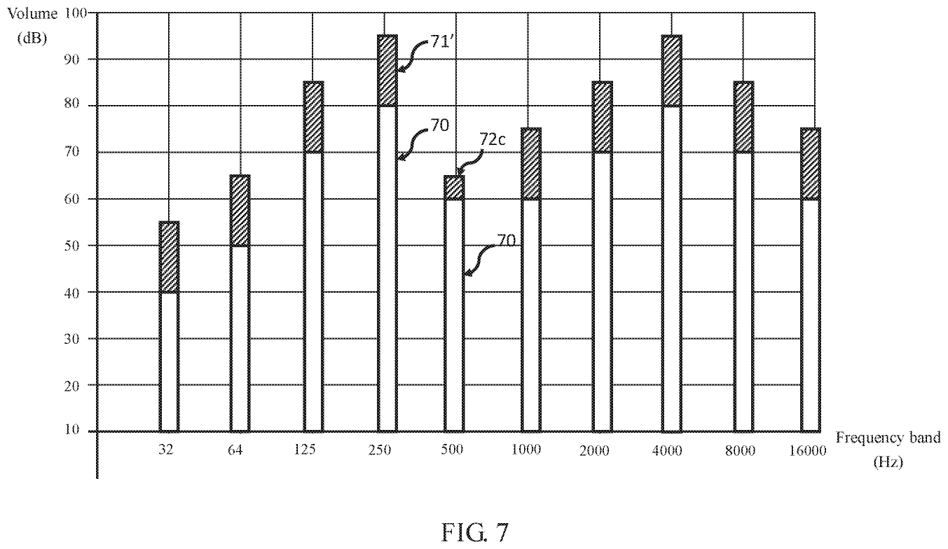

Then, please refer to FIG. 7, which is a waveform diagram of adjusting output sound in a fifth embodiment of the present invention.

The fifth embodiment of the present invention is equivalent to the case in Step 206 where the volume difference of the average noise volume and the average input volume exceeds the threshold. The sound processing module 50 not only increases the first gain value 71′ to the original gain value 70 of the input sound signal that does not belong to the 500 Hz band, but increases the second gain value 72c to the original gain value 70 of the input sound signal belonging to the 500 Hz band. Similarly, the second gain value 72c is less than the first gain value 71′, e,g. 0-5 dB, but the present invention is not limited thereto. Therefore, the output sound signal of the 500 Hz band is equivalent to the original gain value 70 plus the second gain value 72c.

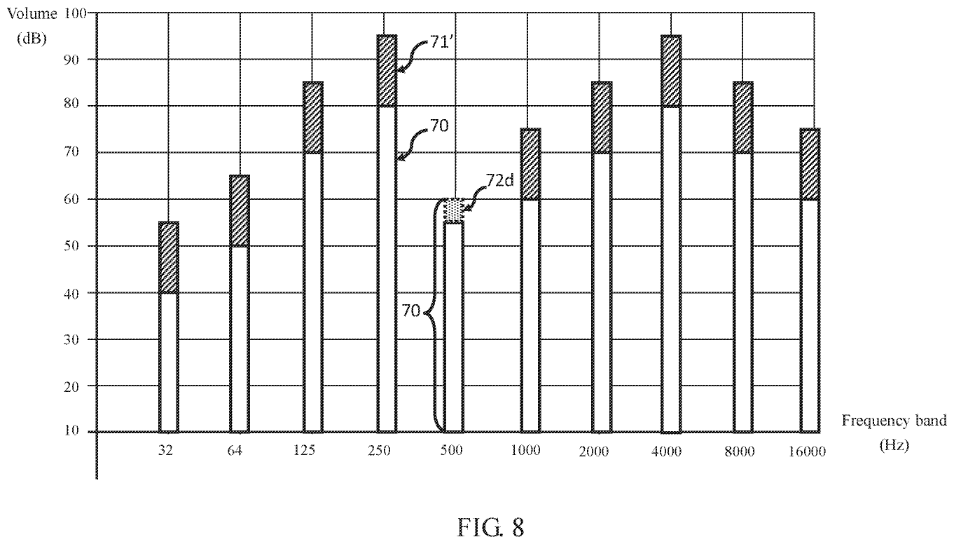

Finally, please refer to FIG. 8, which is a waveform diagram of adjusting output sound in a sixth embodiment of the present invention.

The sixth embodiment of the present invention is equivalent to the case in Step 207 where the volume difference of the average noise volume and the average input volume is less than the threshold. The sound processing module 50 not only increases the first gain value 71′ to the original gain value 70 of the input sound signal that does not belong to the 500 Hz band, but decreases the second gain value 72d from the original gain value 70 of the input sound signal belonging to the 500 Hz band, Similarly, the second gain value 72d is less than the first gain value 71′, e.g. 0-5 dB, but the present invention is not limited thereto. Therefore, the output sound signal of the 500 Hz band is equivalent to the original gain value 70 minus the second gain value 72d.

Finally, in Step 208: Forming and playing an output sound signal.

After the processing of Step 204, Step 206 or Step 207, the sound processing module 50 can form an output sound signal. Therefore, the output sound signal can be adjusted by the first to sixth embodiments. In the first embodiment, the first gain value 71 is increased for the input sound signal that has the same frequency band with the noise frequency band; in the second embodiment, the first gain value 71 is increased for the input sound signal that has the same frequency band with the noise frequency band, and the second gain value 72a is increased for the input sound signal that has a different frequency band with the noise frequency band; in the third embodiment, the first gain value 71 is increased for the input sound signal that has the same frequency band with the noise frequency band, and the second gain value 72b is decreased for the input sound signal that has a different frequency band with the noise frequency band; in the fourth embodiment, the first gain value 71′ is increased for the input sound signal that has a different frequency band with the noise frequency band; in the fifth embodiment, the first gain value 71′ is is increased for the input sound signal that has a different frequency band with the noise frequency band, and the second gain value 72c is increased for the input sound signal that has the same frequency band with the noise frequency band; in the sixth embodiment, the first gain value 71′ is increased for the input sound signal that has a different frequency band with the noise frequency band, and the second gain value 72d is decreased for the input sound signal that has the same frequency band with the noise frequency band. Finally, the speaker module 60 plays the output sound signal. In this way, through the above adjustment method in the first to the sixth embodiment, the output sound signal played by the speaker module 60 can reduce the noise interference to the user.

It should he noted here that the output sound adjusting method of the present invention is not limited to the order of the above steps, and the order of the above steps can be changed as long as the objectives of the present invention are achieved.

From the above description, according to the aforementioned embodiment, the user can reduce the interference of ambient noise when using the sound playback device 10.

It should be noted that the embodiments of the present invention described above are only illustrative. All without departing from the scope of the invention are defined solely by the appended claims.

What is claimed is:

1. An output sound adjusting method, used for a sound playback device, the method comprising the following steps:
obtaining an input sound signal and knowing an average input volume of the input sound signal;
detecting an ambient noise, and analyzing an average noise volume and a noise frequency band of the ambient noise;
determining whether the average noise volume of the ambient noise is louder than the average input volume;
if yes, adjusting a specific frequency band of the input sound signal to increase a first gain value to form an output sound signal, wherein the specific frequency band and the noise frequency band of the ambient noise belongs to the same frequency band or different frequency bands; and
playing the output sound signal.

2. The output sound adjusting method as claimed in claim her comprising the following step:
when the specific frequency band and the noise frequency band of the ambient noise belongs to the same frequency band, adjusting the volume for frequency bands other than the specific frequency band at the same time.

3. The output sound adjusting method as claimed in claim 1, further comprising the following step:
when the specific frequency band and the noise frequency band of the ambient noise belongs to different frequency bands, adjusting the volume for frequency hands other than the specific frequency band at the same time.

4. The output sound adjusting method as claimed in claim 3, further comprising the following step:
if the average noise volume of the ambient noise is louder than the average input volume and the volume and the volume difference exceeds a threshold, further increasing a second gain value for the volume of frequency bands other than the specific frequency band, where the second gain value is less than the first gain value.

5. The output sound adjusting method as claimed in claim 3, further comprising the following step:
wherein if the average noise volume of the ambient noise is louder than the average input volume but the volume difference does not exceed a threshold, further decreasing a second gain value for the volume of frequency bands other than the specific frequency band, where the second gain value is less than the first gain value.

6. The output sound adjusting method as claimed in claim 2, further comprising the following step:
if the average noise volume of the ambient noise is louder than the average input volume and the volume and the volume difference exceeds a threshold, further increasing a second gain value for the volume of frequency bands other than the specific frequency band, where the second gain value is less than the first gain value.

7. The output sound adjusting method as claimed in claim 2, further comprising the following step:
wherein if the average noise volume of the ambient noise is louder than the average input volume but the volume difference does not exceed a threshold, further decreasing a second gain value for the volume of frequency bands other than the specific frequency band, where the second gain value is less than the first gain value.

8. A sound playback device, comprising:
a sound receiving module, which is used to obtain an input sound signal and know average input volume of the input sound signal;
a noise detector, which is used to detect an ambient noise;
a noise analysis module, which is electrically connected to the noise detector, for analyzing an average noise volume and a noise frequency band of the ambient noise to determine whether the average noise volume of the ambient noise is louder than the average input volume;
a sound processing module, which is electrically connected to the sound receiving module and the noise analysis module; if the average noise volume of the noise frequency band is louder than the average input volume, the sound processing module adjusts a specific frequency band of the input sound signal to increase a first gain value to form an output sound signal, wherein the specific frequency band belongs to the same frequency band or different frequency bands; and
a speaker module, which is electrically connected to the sound processing module, for playing the output sound signal.

9. The sound playback device as claimed in claim 8, wherein when the specific frequency band and the noise frequency band of the ambient noise belongs to the same frequency band, the sound processing module adjusts the volume for frequency bands other than the specific frequency band at the same time.

10. The sound playback device as claimed in claim 8, wherein when the specific frequency band and the noise frequency band of the ambient noise belongs to different frequency bands, the sound processing module adjusts the volume for frequency bands other than the specific frequency band at the same time.

11. The sound playback device as claimed in claim 10, wherein if the average noise volume of the ambient noise is louder than the average input volume and the volume difference exceeds a threshold, the sound processing module further increases a second gain value to the volume of frequency bands other than the specific frequency hand, where the second gain value is less than the first gain value.

12. The sound playback device as claimed in claim 10, wherein if the average noise volume of the ambient noise is louder than the average input volume but the volume difference does not exceed a threshold, the sound processing module further decreases a second gain value for the volume of frequency bands other than the specific frequency band, where the second gain value is less than the first gain value.

13. The sound playback device as claimed in claim 9, wherein if the average noise volume of the ambient noise is louder than the average input volume and the volume difference exceeds a threshold, the sound processing module further increases a second gain value to the volume of frequency bands other than the specific frequency band, where the second gain value is less than the first gain value.

14. The sound playback device as claimed in claim 9, wherein if the average noise volume of the ambient noise is louder than the average input volume but the volume difference does not exceed a threshold, the sound processing module further decreases a second gain value for the volume of frequency bands other than the specific frequency band, where the second gain value is less than the first gain value.
